(19) United States
(12) Patent Application Publication
(10) Pub. No.: US 2026/0053017 A1
(43) Pub. Date: Feb. 19, 2026

(54) ELECTRONIC DEVICE AND SEMICONDUCTOR DEVICE

(71) Applicant: Renesas Electronics Corporation, Tokyo (JP)

(72) Inventor: Shuuichi KARIYAZAKI, Tokyo (JP)

(21) Appl. No.: 19/261,127

(22) Filed: Jul. 7, 2025

(30) Foreign Application Priority Data
Aug. 15, 2024 (JP) 2024-135662

(51) Int. Cl. H01L 23/538; H01L 23/498; H01L 25/16; H05K 1/11; H05K 1/18; H10D 1/20; H10D 1/68

(52) U.S. Cl. CPC H01L 23/5385; H01L 23/49816; H01L 23/5386; H01L 25/162; H05K 1/113; H05K 1/181; H10D 1/20; H10D 1/68

(57) ABSTRACT

An electronic device includes a mounting board, a semiconductor device mounted on the mounting board, and a plurality of electronic components mounted on the mounting board. The semiconductor device is electrically connected to the mounting board via a plurality of terminals arranged in a grid on the wiring substrate. The terminals include a plurality of power supply terminals that is capable of supplying a power supply potential to a first circuit of the semiconductor chip. Each of the electronic components EC1 has a passive element and is electrically connected to any of the power supply terminals. At least four or more of the power supply terminals are arranged in an outermost row of the terminals, which is arranged in the grid, such that the four or more power supply terminals are arranged next to each other, and such that the four or more power supply terminals are arranged continuously.

### CROSS-REFERENCE TO RELATED APPLICATIONS

The disclosure of Japanese Patent Application No. 2024-135662 filed on Aug. 15, 2024, including the specification, drawings and abstract is incorporated herein by reference in its entirety.

### BACKGROUND

The present invention relates to an electronic device and a semiconductor device.

There are disclosed techniques listed below.

### [Patent Document 1] Japanese Unexamined Patent Application Publication No. 2015-154062

There is an electronic device in which a semiconductor device and a capacitor are mounted on a mounting board (see, for example, Patent Document 1).

### SUMMARY

The present inventor is considering a technology that can improve the performance of a semiconductor device or an electronic device in which a semiconductor device is mounted on a mounting board. For example, from the perspective of reducing the power consumption of the semiconductor device, it is necessary to reduce the voltage used in various circuits provided in the semiconductor device.

To reduce the voltage used in the circuits, it is necessary to reduce the influence of noise on a supply path of a power-supply potential. When coupling a filter circuit to each supply path of the power-supply potential, as a way to reduce the influence of noise, for example, there is a way of mounting an electronic component for configuring the filter circuit on the mounting board. In this case, the number of the supply paths of the power-supply potential is increased in accordance with the high functionality of the semiconductor device, thereby the number of electronic components to be mounted is also increased.

Other challenges and novel features will become apparent from the description of this specification and the accompanying drawings.

An electronic device according to one embodiment includes a mounting board, a semiconductor device mounted on the mounting board, and a plurality of electronic components mounted on the mounting board. The semiconductor device includes a wiring substrate, and a semiconductor chip mounted on one of surfaces of the wiring substrate. The semiconductor device is electrically connected to the mounting board via a plurality of terminals arranged in a grid on the other of the surfaces of the wiring substrate. The plurality of terminals includes a plurality of first power supply terminals that is capable of supplying a power supply potential to a first circuit of the semiconductor chip. Each of the plurality of electronic components has a passive element and is electrically connected to any of the plurality of first power supply terminals. At least four or more of the plurality of first power supply terminals are arranged in an outermost row of the plurality of terminals, which is arranged in the grid, such that the four or more of the plurality of first power supply terminals are arranged next to each other, and such that the four or more of the plurality of first power supply terminals are arranged continuously.

A semiconductor device according to another embodiment includes a wiring substrate, a semiconductor chip mounted on one of surfaces of the wiring substrate, and a plurality of terminals arranged in a grid on the other of the surfaces of the wiring substrate. The plurality of terminals includes a plurality of first power supply terminals that is capable of supplying a power supply potential to a first circuit of the semiconductor chip. At least four or more of the plurality of first power supply terminals are arranged in an outermost row of the plurality of terminals, which is arranged in the grid, such that the four or more of the plurality of first power supply terminals are arranged next to each other, and such that the four or more of the plurality of first power supply terminals are arranged continuously.

According to the one embodiment, it is possible to improve the performance of the semiconductor device or the electronic device in which the semiconductor device is mounted.

### BRIEF DESCRIPTION OF THE DRAWINGS

FIG. 1 is an enlarged plan view showing an area around a semiconductor device in an electronic device according to one embodiment.

FIG. 2 is a cross-sectional view taken along line A-A of FIG. 1.

FIG. 3 is a cross-sectional view of the semiconductor device shown in FIG. 2.

FIG. 4 is a plan view showing an example of a lower surface of the semiconductor device shown in FIG. 3.

FIG. 5 is an explanatory diagram showing a configuration example of a circuit included in the electronic device shown in FIG. 1.

FIG. 6 is an enlarged plan view showing an area around a terminal coupled to a filter circuit in a mounting board of the electronic device shown in FIG. 1.

FIG. 7 is an explanatory diagram showing a modified example of FIG. 5.

FIG. 8 is an enlarged plan view showing an example of a layout in a wiring layer of the uppermost layer of the mounting board, which is a modified example of FIG. 6.

FIG. 9 is an enlarged plan view showing an example of a layout in a wiring layer of the lowermost layer of the mounting board shown in FIG. 8.

FIG. 10 is an enlarged cross-sectional view taken along line B-B shown in FIGS. 8 and 9.

FIG. 11 is an enlarged plan view showing an example of a layout in the wiring layer of the uppermost layer of the mounting board, which is a modified example of FIG. 8.

FIG. 12 is an enlarged plan view showing an example of a layout in the wiring layer of the lowermost layer of the mounting board shown in FIG. 11.

FIG. 13 is an enlarged plan view showing an example of a wiring pattern in one of a plurality of wiring layers provided in a wiring substrate shown in FIG. 3.

### DETAILED DESCRIPTION

### Description of Format, Basic Terms, and Usage in this Application

In this application, the description of the embodiment is divided into multiple sections for convenience as necessary, but unless specifically stated otherwise, these are not mutually independent and separate, and regardless of the order of description, each part of a single example, one being a part detail or a part or all of a modified example of the other. In principle, descriptions of similar parts are omitted. Also, each component in an embodiment is not essential unless expressly stated otherwise, theoretically limited to that number, and obviously otherwise from the context.

Similarly, in the description of the embodiment and the like, “X consisting of A” or the like with respect to the material, composition, and the like does not exclude elements other than A, except when it is clearly indicated that this is not the case and when it is obvious from the context that this is not the case. For example, regarding a component, it means “X including A as a main component” or the like. For example, “silicon member” does not mean it is limited to pure silicon but also includes SiGe (silicon-germanium) alloys and other multi-component alloys with silicon as the main component, and other additives. Similarly, gold plating, Cu layer, nickel plating, etc., unless specifically stated otherwise, include members with gold, Cu, nickel, etc., as the main component, not just pure ones.

Furthermore, reference to a specific numerical value or quantity may be greater than or less than that specific numerical value, unless expressly stated otherwise, theoretically limited to that number, and obviously not so from the context.

In the drawings of the embodiments, the same or similar parts are denoted by the same or similar symbols or reference numerals, and the description will not be repeated in principle.

In the attached drawings, hatching and the like may be omitted even in a cross-section when it becomes complicated or when it is clearly distinguished from a gap. In this connection, even if the hole is closed in plan, the outline of the background may be omitted when it is obvious from the description or the like. Furthermore, even if not in cross-section, hatching or dot patterns may be used to indicate that it is not a gap or to indicate the boundary of a region.

### Electronic Device

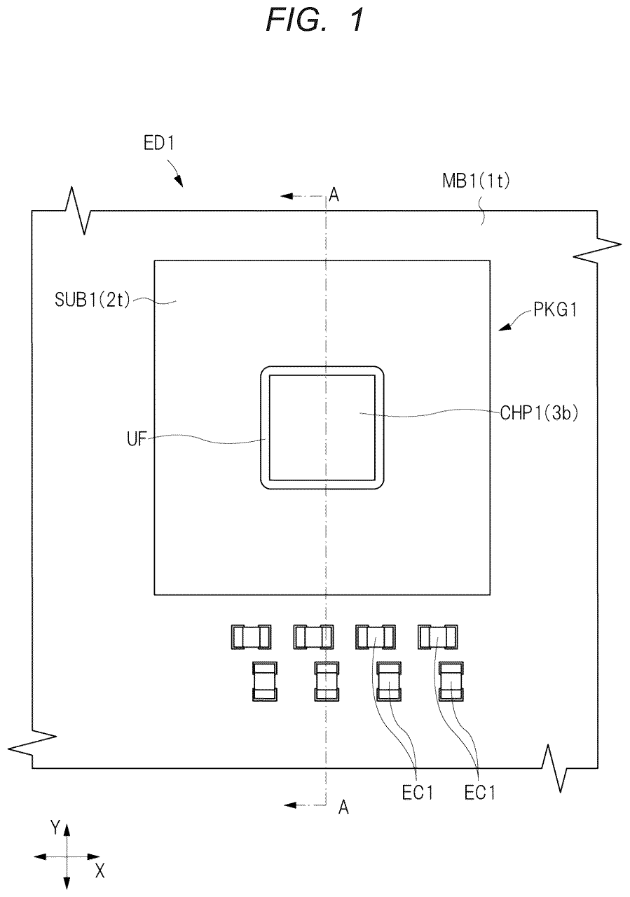

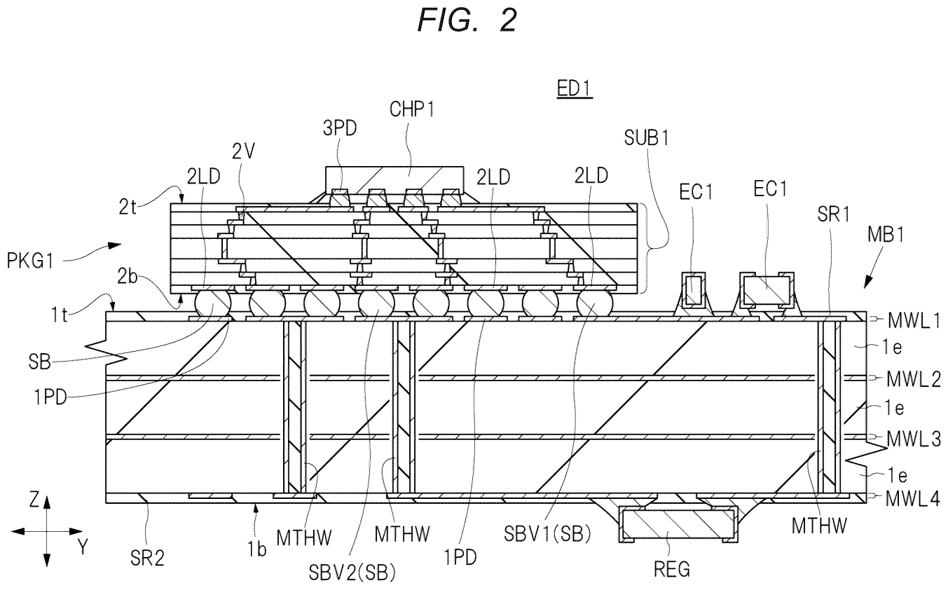

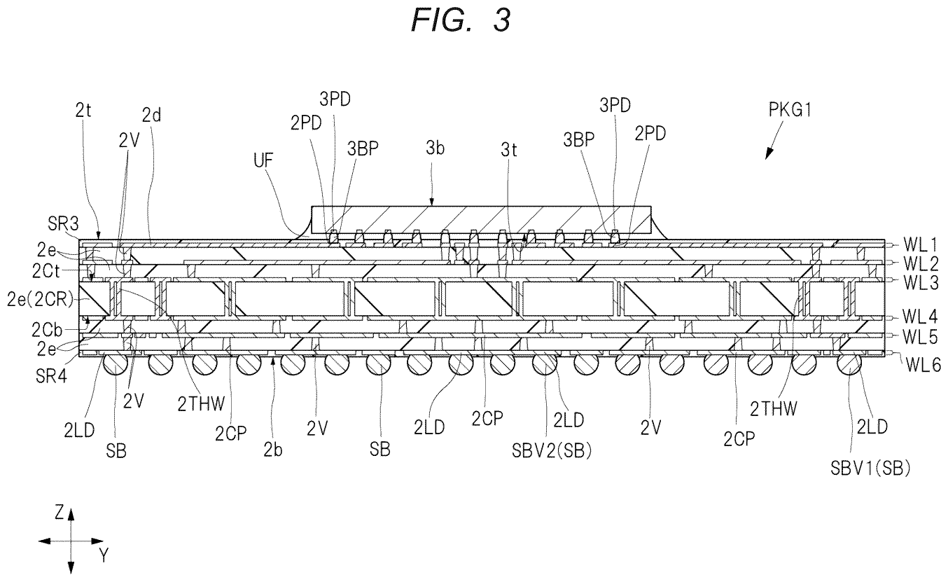

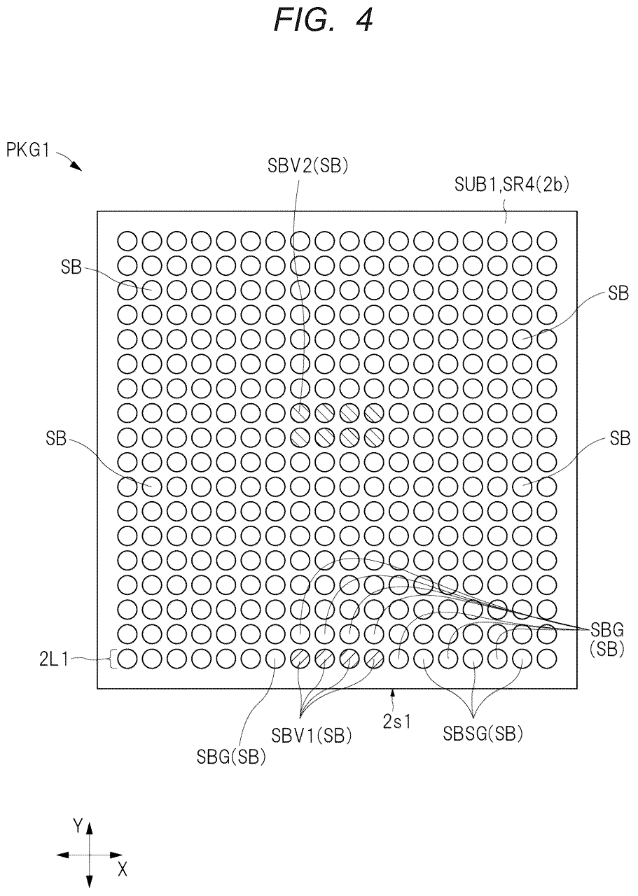

FIG. 1 is an enlarged plan view showing an area around a semiconductor device in an electronic device according to one embodiment. FIG. 2 is a cross-sectional view taken along line A-A of FIG. 1. FIG. 3 is a cross-sectional view of the semiconductor device shown in FIG. 2. FIG. 4 is a plan view showing an example of a lower surface of the semiconductor device shown in FIG. 3. Although FIG. 4 is a plan view, hatching is applied to some of the solder balls SB, specifically, the power-supply terminals SBV1 and SBV2. In FIGS. 1 and 2, for ease of viewing, the number of solder balls SB and the number of electronic components EC1 are shown in reduced numbers. Therefore, the number of terminals (solder balls SB) of the semiconductor device PKG1 and the number of electrodes (electrodes 3PD) of the semiconductor chip CHP1 differ between FIGS. 2 and 3.

In FIGS. 1 and 2, either the X direction (see FIG. 1), the Y direction (see FIGS. 1 and 2), or the Z direction (see FIG. 2) are described. The Y direction is the side intersecting the X direction, and in the following description, the X direction and the Y direction are orthogonal to each other. The Z direction is the orthogonal direction to each of the X direction and the Y direction. In other words, the Z direction is the normal direction to the X-Y plane including the X direction and the Y direction. In the following description, “thickness” means the length in the Z direction in principle. Also, in the following description, “plan view” means a plan view viewed from the X-Y plane in principle.

As shown in FIG. 1, the electronic device ED1 of the present embodiment includes a mounting board MB1, a semiconductor device PKG1 mounted on the mounting board MB1, and a plurality of electronic components EC1 mounted on the mounting board MB1. As shown in FIG. 2, the mounting board MB1 includes an upper surface 1t and a lower surface 1b opposite the upper surface 1t. The semiconductor device PKG1 is mounted on the upper surface 1t of the mounting board MB1. The electronic components EC1 are mounted on the mounting board MB1.

The mounting board MB1 includes a plurality of wiring layers. In the example shown in FIG. 2, the mounting board MB1 includes a wiring layer MWL1, a wiring layer MWL2, a wiring layer MWL3, and a wiring layer MWL4 in order from the upper surface 1t. An insulating layer 1e is interposed between each of the wiring layers. Among the wiring layers, the uppermost layer (the layer closest to the upper surface 1t), wiring layer MWL1, is covered with an insulating film SR1. Among the wiring layers, the lowermost layer (the layer closest to the lower surface 1b), wiring layer MWL4, is covered with an insulating film SR2. Each of the insulating films SR1 and SR2 is a solder resist film made of an organic material capable of suppressing the spread of solder, for example. The number of wiring layers provided in the mounting board MB1 is not limited to four layers, and various modified examples exist.

Each of the wiring layers MWL1, MWL2, MWL3, and MWL4 have a conductor pattern formed thereon. An example of the conductor pattern formed on the wiring layer MWL1 will be described later. The mounting board MB1 has a plurality of through-hole wirings MTHW that penetrate the mounting board MB1 in the thickness direction. Each of the wiring layers is electrically connected to each other through the through-hole wiring MTHW. In this way, the mounting board MB1, in which wiring layers are electrically connected to each other through the through-hole wirings MTHW that penetrate three or more insulating layers 1e, is easier to multilayer compared to a so-called build-up substrate. A wiring substrate with through-hole wirings MTHW penetrating three or more insulating layers, like the mounting board MB1, is called a multilayer through substrate.

As will be described in detail later, the wiring substrate SUB1 of the semiconductor device PKG1 has wiring layers adjacent to each other in the thickness direction electrically connected through a plurality of via wirings 2V. The wiring substrate SUB1 is a build-up substrate. A build-up substrate like the wiring substrate SUB1 is more complex in manufacturing process compared to a multilayer through substrate like the mounting board MB1, but it is advantageous in terms of the freedom of wiring layout.

The semiconductor device PKG1 shown in FIG. 1 and FIG. 2 includes a wiring substrate SUB1 and a semiconductor chip CHP1 mounted on the wiring substrate SUB1.

As shown in FIG. 1, the semiconductor device PKG1 of the present embodiment includes a wiring substrate SUB1 and a semiconductor chip CHP1 mounted on the wiring substrate SUB1. As shown in FIG. 2 and FIG. 3, the wiring substrate SUB1 of the semiconductor device PKG1 has an upper surface 2t, which is a chip mounting surface, and a lower surface 2b opposite the upper surface 2t. The lower surface 2b functions as the mounting surface of the semiconductor device PKG1.

As shown in FIG. 3, the wiring substrate SUB1 (see FIG. 2) of the semiconductor device PKG1 has a plurality of internal interface terminals (pads 2PD) exposed from the insulating film SR3 on the upper surface 2t and a plurality of external interface terminals (lands 2LD) exposed from the insulating film SR4 on the lower surface 2b, which is the mounting surface.

The wiring substrate SUB1 also has the wiring layers that electrically connect the internal interface terminals and the external interface terminals. In the example shown in FIG. 3, the wiring substrate SUB1 is a six-layer structure wiring substrate with wiring layers WL1, WL2, WL3, WL4, WL5, and WL6. However, the number of wiring layers in the wiring substrate SUB1 is not limited to six layers and may be five layers or less, or seven layers or more.

Each wiring layer is located between the upper surface 2t and the lower surface 2b. Each wiring layer has conductor patterns such as wiring that serve as paths for supplying electrical signals and power. Each wiring layer is electrically connected to each other through the via wirings 2V or a plurality of through-hole wirings 2THW that penetrates through the insulating layer 2e. An insulating layer 2e is placed between each wiring layer. The plurality of insulating layers 2e each placed between each wiring layer includes a core insulating layer (insulating layer, core material, core insulating layer) 2CR placed between the upper surface 2t and the lower surface 2b. The core insulating layer 2CR is a core member for ensuring the rigidity of the wiring substrate SUB1 and is made of, for example, a prepreg impregnated with resin in glass fiber.

Among the wiring layers, the wiring layer WL1 placed closest to the upper surface 2t is covered with the insulating film SR3. The insulating film SR3 has openings, and each of the pads 2PD provided in the wiring layer WL1 is exposed from the insulating film SR3 at the openings.

Among the wiring layers, the wiring layer WL6 placed closest to the lower surface 2b of the wiring substrate SUB1 has the lands 2LD provided. The wiring layer WL6 is covered with the insulating film SR4. Each of the insulating films SR3 and SR4 is a solder resist film made of an organic material capable of suppressing the spread of solder. Each of the pads 2PD provided in the wiring layer WL1 and each of the lands 2LD provided in the wiring layer WL4 are electrically connected through conductor patterns (wiring 2d and large-area conductor pattern 2CP) formed in each wiring layer of the wiring substrate SUB1, the via wirings 2V, and the through-hole wirings 2THW.

Each of the wiring 2d, the pads 2PD, the via wirings 2V, via lands (not shown), through-hole lands (not shown), the through-hole wirings 2THW, the lands 2LD, and conductor patterns 2CP is made of, for example, a metal material mainly composed of copper or copper.

The wiring substrate SUB1 is formed by laminating the wiring layers on the upper surface 2Ct and the lower surface 2Cb of the core insulating layer (insulating layer, core material, core insulating layer) 2CR using a build-up method. Also, the wiring layer WL2 on the upper surface 2Ct side and the wiring layer WL3 on the lower surface 2Cb side of the core insulating layer 2CR are electrically connected through the through-hole wirings 2THW embedded in the through-holes (through-holes) provided to penetrate from one of the upper surfaces 2Ct and the lower surface 2Cb to the other.

A plurality of solder balls (solder material, external terminals, electrodes, external electrodes) SB is formed on the lower surface 2b of the wiring substrate SUB1. Specifically, the solder balls SB are connected to each of the lands 2LD of the wiring substrate SUB1. The solder balls SB are a conductive member that electrically connects a plurality of terminals 1PD (see FIG. 2) of the mounting board MB1 and the plurality of lands 2LD (see FIG. 2) to each other, respectively, when mounting the semiconductor device PKG1 on the mounting board MB1. In other words, the wiring substrate SUB1 is electrically connected to the mounting board MB1 through the solder balls SB.

The solder balls SB are made of, for example, a solder material consisting of Sn—Pb solder material containing lead (Pb) or a so-called lead-free solder that substantially does not contain Pb. Examples of lead-free solder include, for example, tin (Sn) only, tin-bismuth (Sn—Bi), or tin-copper-silver (Sn—Cu—Ag), tin-copper (Sn—Cu), and the like. Here, lead-free solder means those with a lead (Pb) content of 0.1 wt % or less, and this content is defined as a standard by the RoHS (Restriction of Hazardous Substances) directive.

As shown in FIG. 4, the solder balls SB are arranged regularly (for example, in a grid or matrix). In other words, the solder balls SB are arranged in a grid on the lower surface 2b of the wiring substrate SUB1. Although not shown in FIG. 4, the lands 2LD (see FIG. 3) to which the solder balls SB are joined are also arranged in a grid (or matrix). A semiconductor device with the external terminals (solder balls SB, lands 2LD) arranged in a matrix on the mounting surface side of the wiring substrate SUB1 is called an area array type semiconductor device.

The area array type semiconductor device can effectively utilize the mounting surface (lower surface 2b) side of the wiring substrate SUB1 as a space for arranging external terminals, making it preferable in that it can suppress the increase in the mounting area of the semiconductor device even if the number of external terminals increases. In other words, it is possible to mount a semiconductor device with an increasing number of external terminals due to higher functionality and higher integration in a space-saving manner.

The semiconductor device PKG1 has a semiconductor chip CHP1 mounted on the wiring substrate SUB1. As shown in FIG. 3, each semiconductor chip CHP1 has a surface (main surface, upper surface) 3t on which a plurality of protruding electrodes 3BP are arranged and a back surface (main surface, lower surface) 3b opposite to the surface 3t.

The semiconductor chip CHP1 forms a rectangular outer shape with a smaller planar area than the wiring substrate SUB1 in a plan view, as shown in FIG. 1. In the example shown in FIG. 1, the semiconductor chip CHP1 is mounted in the central part of the upper surface 2t of the wiring substrate SUB1. Also, each of the four sides of the semiconductor chip CHP1 extends along each of the four sides of the upper surface 2t of the wiring substrate SUB1.

As shown in FIG. 3, the electrodes (pads, electrode pads, bonding pads) 3PD are formed on the surface 3t side of the semiconductor chip CHP1. The surface 3t is the outermost surface of the semiconductor chip CHP1. The surface 3t includes the upper surface of a passivation film not shown and the upper surface of the electrode 3PD exposed from the passivation film. Since the protruding electrodes 3BP are formed on the electrode 3PD, it can be expressed that the protruding electrodes 3BP are formed on the surface 3t.

In the example shown in FIG. 3, the semiconductor chip CHP1 is mounted on the wiring substrate SUB1 with the surface 3t facing the upper surface 2t of the wiring substrate SUB1. This mounting method is called a face-down mounting method or a flip-chip connection method.

Although not shown, the semiconductor elements (circuit elements) are formed in the main surface (specifically, a semiconductor element formation region provided on an element formation surface of semiconductor substrate, which is the base material of the semiconductor chip CHP1) of the semiconductor chip CHP1. The electrodes 3PD are electrically connected to the semiconductor elements, respectively, the via wirings (not shown) formed in the wiring layer placed inside the semiconductor chip CHP1 (specifically, between the surface 3t and the semiconductor element formation region not shown). An example of the circuit configuration provided in the semiconductor chip CHP1 will be described later.

The semiconductor chip CHP1 (specifically, the semiconductor substrate of the semiconductor chip CHP1) is made of, for example, silicon (Si). Additionally, on the surface 3t, an insulating film (a passivation film not shown in the figure) covering the semiconductor substrate and wiring of the semiconductor chip CHP1 is formed, and a part of each of the electrodes 3PD is exposed from the passivation film at the openings formed in the passivation film. Furthermore, each of the electrodes 3PD is made of metal, and in the present embodiment, they are made of, for example, aluminum (Al).

As shown in FIG. 3, a protruding electrode 3BP is connected to each of the electrodes 3PD, and the electrodes 3PD of the semiconductor chip CHP1 and the pads 2PD of the wiring substrate SUB1 are electrically connected to each other, respectively, via the protruding electrodes 3BP. The protruding electrode (bump electrode) 3BP is a metal member (conductive member) formed to protrude on the surface 3t of the semiconductor chip CHP1. Examples of the protruding electrode 3BP include columnar electrodes made of copper or nickel (so-called copper pillar electrodes) or micro solder balls.

Additionally, as shown in FIG. 3, underfill resin (insulating resin) UF is placed between the semiconductor chip CHP1 and the wiring substrate SUB1. The underfill resin UF is arranged to fill the space between the surface 3t of the semiconductor chip CHP1 and the upper surface 2t of the wiring substrate SUB1. Each of the protruding electrodes 3BP is sealed by the underfill resin UF. The underfill resin UF is made of an insulating (non-conductive) material (for example, resin material) and is arranged to seal the electrical connection parts (junctions of the protruding electrodes 3BP) between the semiconductor chip CHP1 and the wiring substrate SUB1.

In the present embodiment, an example of a method for electrically connecting the semiconductor chip CHP1 and the wiring substrate SUB1 using a flip-chip connection method is illustrated and described. However, there are various modified examples of the connection method between the semiconductor chip CHP1 and the wiring substrate SUB1. Although not shown, for example, the electrode 3PD of the semiconductor chip CHP1 and the pad 2PD of the wiring substrate SUB1 may be electrically connected via a wire not shown in the figure. In this case, the semiconductor chip CHP1 is mounted on the wiring substrate SUB1 with the back surface 3b facing the upper surface 2t of the wiring substrate SUB1 through an adhesive (die bond material) not shown in the figure. This mounting method is called the face-up mounting method.

The electronic components EC1 mounted on the mounting board MB1 are an electronic component having a passive element such as a capacitor element, an inductor element, or a resistor element. Each of the electronic components EC1 is a so-called surface-mounted component mounted on the upper surface 1t or the lower surface 1b of the mounting board MB1 via solder. In the example shown in FIG. 2, each of the electronic components EC1 is mounted on the upper surface 1t of the mounting board MB1. A surface-mounted component having a capacitor element is called a chip capacitor, a surface-mounted component having an inductor element is called a chip inductor, and a surface-mounted component having a resistor element is called a chip resistor.

As will be described in detail later, each of the electronic components EC1 is connected to a path that supplies power-supply potential to the semiconductor chip CHP1, forming a filter circuit. Therefore, the electronic components EC1 are connected to a power-supply source, the regulator REG (see FIG. 2). Although the regulator REG itself is a type of electronic component, the present embodiment distinguishes between the regulator REG, which is a power-supply source, and the electronic components EC1, which are components of the filter circuit.

In the example shown in FIG. 2, the regulator REG is mounted on the lower surface 1b of the mounting board MB1 and is electrically connected to the electronic components EC1 via through-hole wiring MTHW. However, the mounting position of the regulator REG is not limited to the lower surface 1b and may be mounted on the upper surface 1t.

### Example of Circuit Configuration

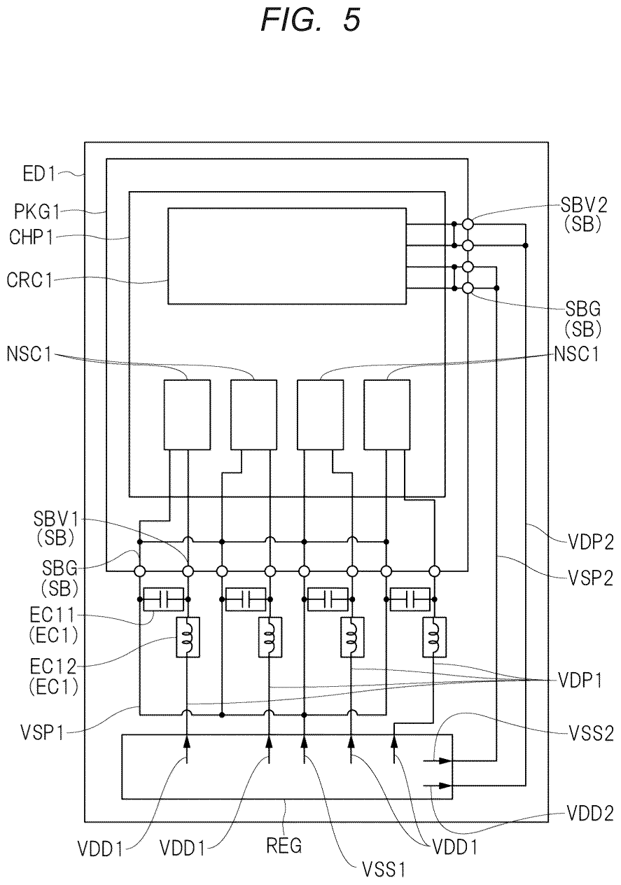

Next, an example of the circuit configuration of the electronic device ED1 shown in FIG. 1 will be described. FIG. 5 is an explanatory diagram showing an example of the circuit configuration of the electronic device shown in FIG. 1. The electronic device ED1 has various circuits, such as a path for supplying power to the semiconductor chip CHP1 or a path for transmitting signals. Among the circuits provided in the electronic device ED1, the circuits that supply power-supply potential and reference potential to each of a core circuit CRC1 and a circuit NSC1 which are provided in the semiconductor chip CHP1 are shown in FIG. 5.

As shown in FIG. 5, the semiconductor chip CHP1 of the electronic device ED1 in the present embodiment includes a core circuit CRC1 and the circuits NSC1 different from the core circuit CRC1. The core circuit is a circuit that includes an arithmetic processing circuit. On the other hand, each of the circuits NSC1 is a circuit that is more susceptible to a decrease in operational reliability due to the influence of noise contained in the power compared to the core circuit CRC1. The circuit NSC1 can be rephrased as a circuit sensitive to power noise.

An example of a circuit that is susceptible to a decrease in operational reliability due to the influence of noise contained in the power includes a circuit that includes a clock signal generation circuit, such as a PLL (Phase-Locked Loop) circuit, which generates a clock signal. Additionally, an input/output circuit of a high-speed interface or a memory interface is also an example of the circuit sensitive to the above-mentioned power noise (circuit NSC1 shown in FIG. 5). Examples of high-speed interface circuits include USB (Universal Serial Bus), a type of PCI (Peripheral Component Interconnect) bus standard, and Ethernet. As memory interfaces, DDR (Double Data Rate) and LPDDR can be exemplified. Alternatively, analog circuits such as sensor circuits, AD converters, and DA converters are also examples of circuits sensitive to the above-mentioned power noise (circuit NSC1 shown in FIG. 5).

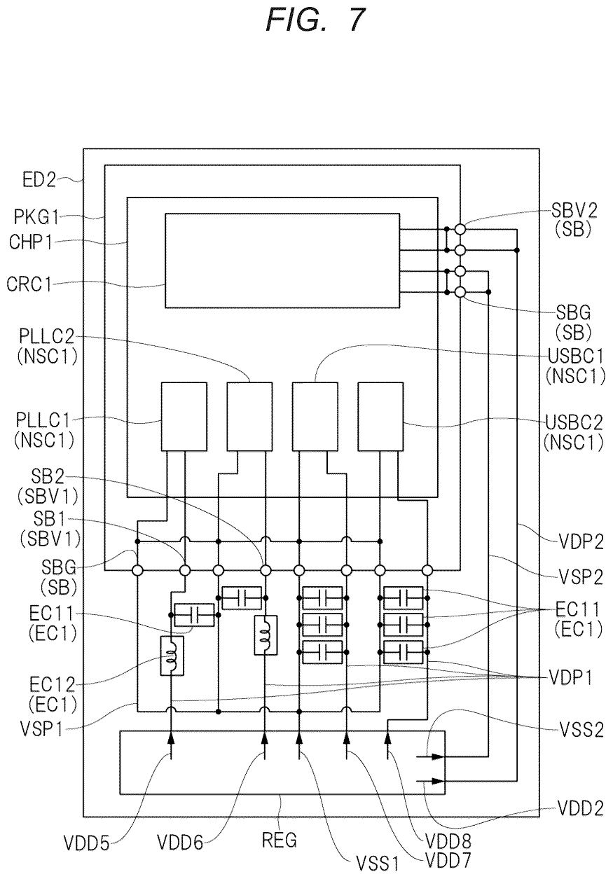

For simplicity of explanation, an example in which the same power-supply potential VDD1 as each other is supplied to each of the four circuits NSC1 is shown in FIG. 5. However, as a modified example of FIG. 5, as shown in FIG. 7, the semiconductor chip CHP1 may have the circuits NSC1, and each of the circuits NSC1 may be supplied with different power-supply potentials VDD5, VDD6, VDD7, or VDD8. Additionally, the above-mentioned circuits NSC1 may include circuits of different types (for example, two or more types of a PLL circuit, an input/output circuit and a temperature sensor circuit).

The electronic device ED1 has a power-supply-potential supply path VDP1 that is capable of supplying the power-supply potential VDD1 to the circuit NSC1 and a reference-potential supply path VSP1 that is capable of supplying a reference potential VSS1 to the circuit NSC1. The reference potential VSS1 is, for example, ground potential.

As described above, the example shown in FIG. 5 illustrates an example in which the same power-supply potential VDD1 as each other is supplied to each of the four power-supply-potential supply paths VDP1. Even when the same power-supply potential VDD1 is supplied to the four power-supply-potential supply paths VDP1, it is preferable that the power-supply-potential supply paths VDP1 are separated from each other. This is to prevent the influence of noise generated in some of the four circuits NSC1 from affecting other circuits NSC1. As described above, as a modified example of the present embodiment, different power-supply potentials may be supplied to the power-supply-potential supply paths VDP1.

Also, the electronic device ED1 has a power-supply-potential supply path VDP2 that is capable of supplying the power-supply potential VDD2 to the core circuit CRC1 and a reference-potential supply path VSP2 that is capable of supplying the reference potential VSS2 to the core circuit CRC1. A power-supply potential VDD2 is, for example, a potential different from the power-supply potential VDD1. Additionally, the reference potential VSS2 is, for example, ground potential similar to the reference potential VSS1. However, the reference potential VSS2 may be a potential different from the reference potential VSS1.

Here, it is preferable that a filter circuit for reducing power noise (in other words, a filter circuit for filtering noise) is connected to the power-supply-potential supply path VDP1 that supplies the power-supply potential VDD1 to the circuit NSC1, which is sensitive to power noise. In the example shown in FIG. 5, as an example of the filter circuit, a low-pass filter circuit is composed of a chip capacitor EC11 having a capacitor element and a chip inductor EC12 having an inductor element is connected to the power-supply-potential supply path VDP1. The configuration of the filter circuit is not limited to the mode exemplified in FIG. 5, and as will be described later, there are various modified examples such as RC circuits, capacitor array circuits, or combinations thereof.

From the perspective of reducing the influence of power noise on the circuit NSC1, it is preferable that the path distance between the circuit NSC1 and the filter circuit is short. This is because shortening the path distance between the circuit NSC1 and the filter circuit can reduce the possibility of noise components reoccurring in the power-supply potential after filtering.

On the other hand, as in the present embodiment, when the filter circuit is composed of the electronic components EC1, it is necessary to secure space for mounting the electronic components EC1. In particular, if the number of required filter circuits increases, the number of required electronic components EC1 also increases accordingly.

For example, as an embodiment that can shorten the path distance between circuit NSC1 and the filter circuit, a configuration is conceivable where the electronic components EC1 are arranged in the area overlapping with the semiconductor chip CHP1 shown in FIG. 2. However, the area overlapping with the semiconductor chip CHP1 is limited in size, and if the number of electronic components EC1 increases, it may not be possible to accommodate some of the electronic components EC1.

### Layout of Electronic Component Composing Filter Circuit

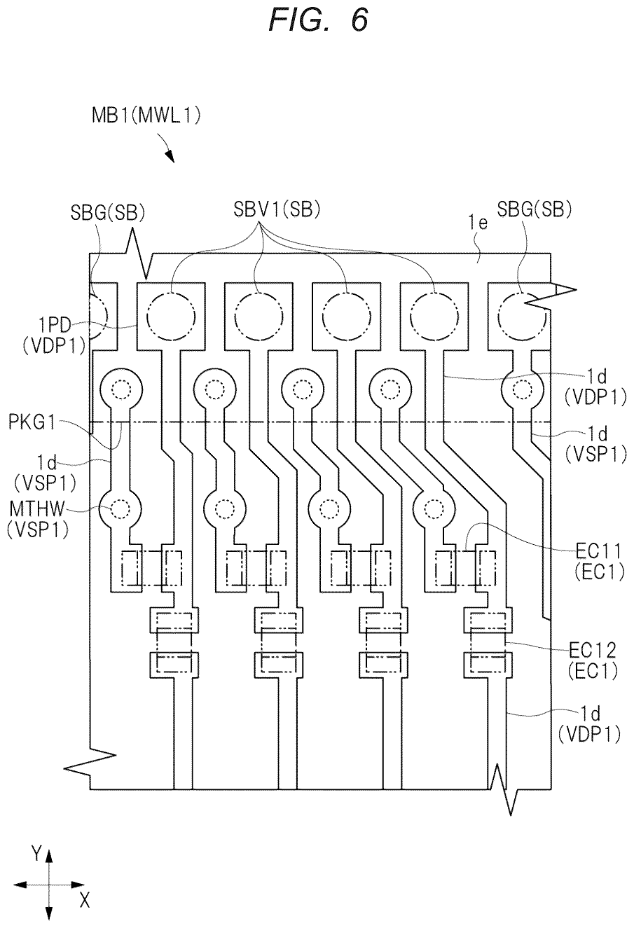

Next, as described above, a method of shortening the path distance between the filter circuit shown in FIG. 5 and the circuit NSC1 while securing space for mounting the electronic components EC1 will be described in detail. FIG. 6 is an enlarged plan view showing an area around a terminal coupled to a filter circuit of a mounting board of the electronic device shown in FIG. 1. In FIG. 6, the shape of the wiring layer MWL1 is shown with a solid line in a state where the insulating film SR1 shown in FIG. 2 is removed. Also, in FIG. 6, the outline of the semiconductor device PKG1 shown in FIG. 1, the outline of the terminal SBV1 shown in FIG. 4, and the outline of the electronic components EC1 are shown with a two-dot chain line.

As shown in FIG. 5, the plurality of solder balls SB (terminals) includes a plurality of power-supply terminals SBV1 that is capable of supplying the power-supply potential VDD1 to the circuits NSC1. As shown in FIGS. 4 and 6, at least four or more of the plurality of solder balls SB (power-supply terminals SBV1) are arranged in the outermost row of the plurality of solder balls SB (terminals), which is arranged in the grid, such that the four or more of the plurality of solder balls SB (power-supply terminals SBV1) are arranged next to each other, and such that the four or more of the plurality of solder balls SB (power-supply terminals SBV1) are arranged continuously.

Also, as described with reference to FIGS. 1 and 2, each of the electronic components EC1 is mounted on the upper surface 1t of the mounting board MB1. In other words, the filter circuit connected to the power-supply-potential supply path VDP1 connected to each of the power-supply terminals SBV1 shown in FIG. 6 is formed on the upper surface 1t of the mounting board MB1 (see FIG. 2).

For example, in the example shown in FIG. 6, each of the chip capacitors EC11 and the chip inductor EC12 constituting the filter circuit is connected to the power-supply terminal SBV1 via the wiring 1d formed in the top wiring layer MWL1 of the mounting board MB1. Also, each of the chip capacitor EC11 and the chip inductor EC12 is connected to the power-supply terminal SBV1 without passing through wiring layers other than the wiring layer MWL1 of the mounting board MB1 (for example, the wiring layer MWL2, wiring layer MWL3, and wiring layer MWL4 shown in FIG. 2).

As is obvious from FIG. 6, according to the present embodiment, since the wiring 1d arranged in the wiring layer MWL1 is connected to each of the power-supply terminal SBV1 and the electronic component EC1, the path distance between the power-supply terminal SBV1 and the filter circuit can be shortened. Therefore, it is possible to reduce the noise component included in the power-supply potential VDD1 (see FIG. 5) input to the power-supply terminal SBV1.

Meanwhile, in the arrangement of the solder balls SB shown in FIG. 4, the outermost row often has the solder balls SB mainly for signal transmission. The solder balls SB include signal terminals SBSG, which are terminals for signal transmission. In the example shown in FIG. 4, row 2L1, which is the outermost row extending along the side 2s1 of the wiring substrate SUB1, has the power-supply terminals SBV1 and the signal terminals SBSG arranged. In this case, it is necessary to reduce the mutual noise impact between the signal transmission path and the power-supply-potential supply path VDP1 (see FIG. 6).

In the case of the present embodiment, in the arrangement of the solder balls SB, at least four or more of the power-supply terminals SBV1 are arranged continuously and adjacent to each other in the outermost row (specifically, row 2L1 along the side 2s1 extending in the X direction). In other words, the power-supply terminals SBV1 are consolidated in part of the row 2L1.

By arranging the power-supply terminals SBV1 in this way, even when the power-supply terminals SBV1 are arranged in the outermost row, it is possible to suppress mutual interference between the signal transmission path and the power-supply-potential supply path VDP1 (see FIG. 6).

Specifically, the solder balls SB include reference potential terminals SBG to which the reference potential VSS1 (see FIG. 5) is supplied. Next to each of the power-supply terminals SBV1, a power-supply terminal SBV1 or a reference potential terminal SBG is arranged. The reference-potential supply path VSP1 shown in FIG. 5 can function as an electromagnetic shield to reduce electromagnetic effects. Therefore, by interposing the reference-potential supply path VSP1 between the signal transmission path and the power-supply-potential supply path VDP1, interference between the signal transmission path and the power-supply-potential supply path VDP1 can be suppressed.

The filter circuit that filters the noise of the power-supply potential VDD1 has various modifications, such as an RC circuit combining a chip resistor and a chip capacitor, in addition to the LC circuit exemplified in FIG. 5, or a capacitor array circuit in which the chip capacitors EC11 are connected in parallel as shown in FIG. 7 described later. Also, if it is a circuit capable of removing noise input to the power-supply-potential supply path VDP1, circuits other than the above may be used. These filter circuits all include two or more electronic components EC1. Therefore, the manner in which each of the power-supply terminals SBV1 shown in FIG. 6 is connected to such a filter circuit can be rephrased as follows. That is, each of the power-supply terminals SBV1 is electrically connected to at least two or more of the electronic components EC1.

When two or more electronic components EC1 are connected to each of the power-supply terminals SBV1, the number of electronic components EC1 becomes twice or more than the number of power-supply terminals SBV1. In this case, as described with reference to FIG. 4, the continuous arrangement of four or more power-supply terminals SBV1 in the outermost row is particularly preferable in terms of securing the placement space for electronic components EC1 while shortening the path distance to the circuit NSC1 (see FIG. 5).

Meanwhile, as shown in FIG. 4, the plurality of solder balls SB (terminals) includes a plurality of solder balls SB (power-supply terminals SBV2) that is capable of supplying the power-supply potential VDD2 (see FIG. 5) to the core circuit CRC1 (see FIG. 5). In the plurality of solder balls SB (terminals) arranged in the grid, each of the plurality of power-supply terminals SBV2 is arranged in an inner row than the plurality of power-supply terminals SBV1. Specifically, each of the plurality of power-supply terminals SBV2 is arranged in a region overlapping with the semiconductor chip CHP1 in the thick direction (Z direction) of the semiconductor device PKG1 shown in FIG. 2.

The core circuit CRC1 shown in FIG. 5 consumes more power per unit time compared to the circuit NSC1. In other words, a large current flow in the power-supply-potential supply path VDP2 that supplies the power-supply potential VDD2 to the core circuit CRC1 compared to the power-supply-potential supply path VDP1. Therefore, it is preferable to shorten the path distance from the regulator REG to the core circuit CRC1. Accordingly, in the case of the present embodiment, each of the power-supply terminals SBV2 is arranged in the region overlapping with the semiconductor chip CHP1 in the thickness direction of the semiconductor device PKG1, in other words, in the central region of the lower surface 2b of the wiring substrate SUB1 shown in FIG. 4. The central region of the lower surface 2b is the region including the center of the lower surface 2b and is distinguished from the peripheral region of the lower surface 2b where the power-supply terminals SBV1 are arranged.

In the example shown in FIG. 2, the power-supply terminal SBV2 is connected to the regulator REG without passing through electronic components. However, as a modification, electronic components such as a bypass capacitor may be connected between the regulator REG and the power-supply terminal SBV2 on the lower surface 1b of the mounting board MB1.

### Modified Example of Circuit

Next, a modified example of the circuit configuration for the electronic device ED1 described with reference to FIG. 5 will be explained. FIG. 7 is an explanatory diagram showing a modified example of FIG. 5. The electronic device ED2 shown in FIG. 7 differs from the electronic device ED1 shown in FIG. 5 in the following points.

The electronic device ED2 differs from the electronic device ED1 shown in FIG. 5 in that it includes multiple types of circuits NSC1. The circuits NSC1 included in the electronic device ED2 include the circuit PLLC1 and the circuit PLLC2, which are PLL circuits. Also, the circuits NSC1 included in the electronic device ED2 include the circuit USBC1 and the circuit USBC2, which are an input/output circuit of the USB standard. In the example shown in FIG. 7, the circuits NSC1 are composed of two types of circuits, but the types and number of circuits constituting the circuits NSC1 are not limited to the embodiments shown in FIG. 5 or FIG. 7. For example, the circuits NSC1 may include three or more types of circuits. Alternatively, the number of the circuits NSC1 may be five or more.

In this modified example, when the electronic device ED2 is equipped with multiple types of circuits NSC1, it is particularly preferable that the power-supply-potential supply paths VDP1, which supply power-supply potential to the circuits NSC1, are isolated from each other. In this modified example, the power-supply potential VDD5 is supplied to the circuit PLLC1, the power-supply potential VDD6 is supplied to the circuit PLLC2, the power-supply potential VDD7 is supplied to the circuit USBC1, and the power-supply potential VDD8 is supplied to the circuit USBC2. Each of the power-supply potentials VDD5, VDD6, VDD7, and VDD8, for example, are different from each other. In other words, the power-supply terminals SBV1 include a terminal SB1, to which the power-supply potential VDD5 is supplied, and a terminal SB2, to which a power-supply potential VDD6 different from the power-supply potential VDD5 is supplied.

In this way, when the power-supply-potential supply paths VDP1 that supply power-supply potentials to the circuits NSC1 are isolated from each other, it becomes difficult to increase the cross-sectional area of each of the power-supply-potential supply paths VDP1. Therefore, it becomes necessary to connect a filter circuit to each of the power-supply-potential supply paths VDP1 to filter noise.

In the case of the electronic device ED2 shown in FIG. 7, it differs from the electronic device ED1 shown in FIG. 5 in that the configuration of the filter circuits connected to the circuits NSC1 is different from each other. For example, each of the circuits PLLC1 and PLLC2 is connected to an LC circuit composed of the chip capacitor EC11 and the chip inductor EC12.

Additionally, each of the circuits USBC1 and USBC2 are connected to a capacitor array in which the chip capacitors EC11 are connected in parallel.

In the example shown in FIG. 7, the reference-potential supply paths VSP1 supplying reference potential to each of the circuits PLLC1, PLLC2, USBC1, and USBC2 are electrically connected to each other. The reference potential supplied to each of the circuits NSC1 is the same potential (for example, ground potential), and the reference-potential supply path VSP1 is easily shared. The reference-potential supply path VSP1 is connected to a large-area conductor pattern (for example, called a ground plane, a large-area conductor pattern to which ground potential is supplied). In this case, even if current flows through the reference-potential supply path VSP1 due to the influence of noise generated in any of the circuits NSC1, the value of the reference potential VSS1 is unlikely to change.

Note that the reference potential VSS1 supplied to the circuits NSC1 and the reference potential VSS2 supplied to the core circuit CRC1 are, for example, the same potential. However, as a modified example, the reference potential VSS1 and the reference potential VSS2 may be different potentials.

The electronic device ED2 shown in FIG. 7 is similar to the electronic device ED1 described using FIG. 5, except for the differences mentioned above. Therefore, overlapping descriptions are omitted.

### Modified Example of Layout of Electronic Component

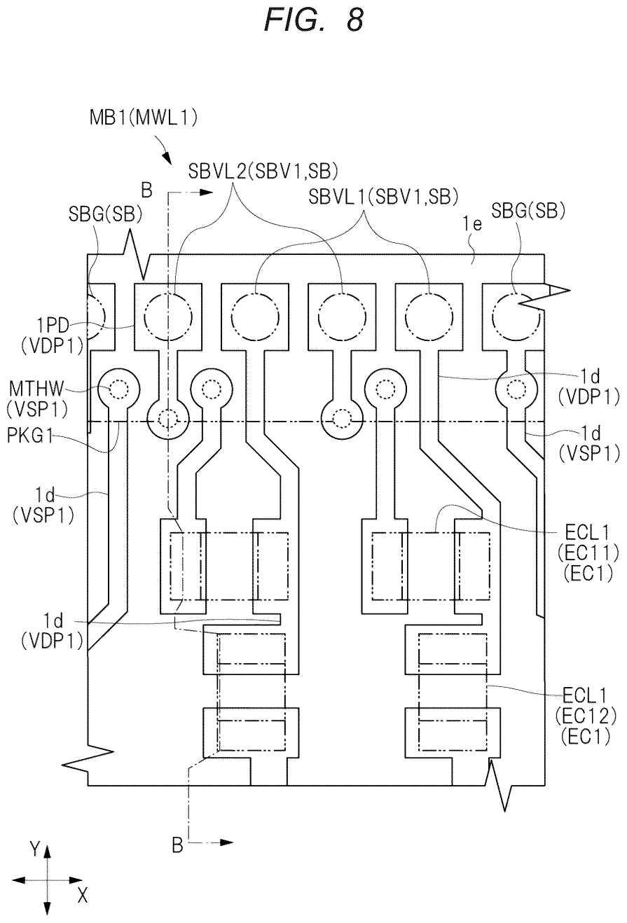

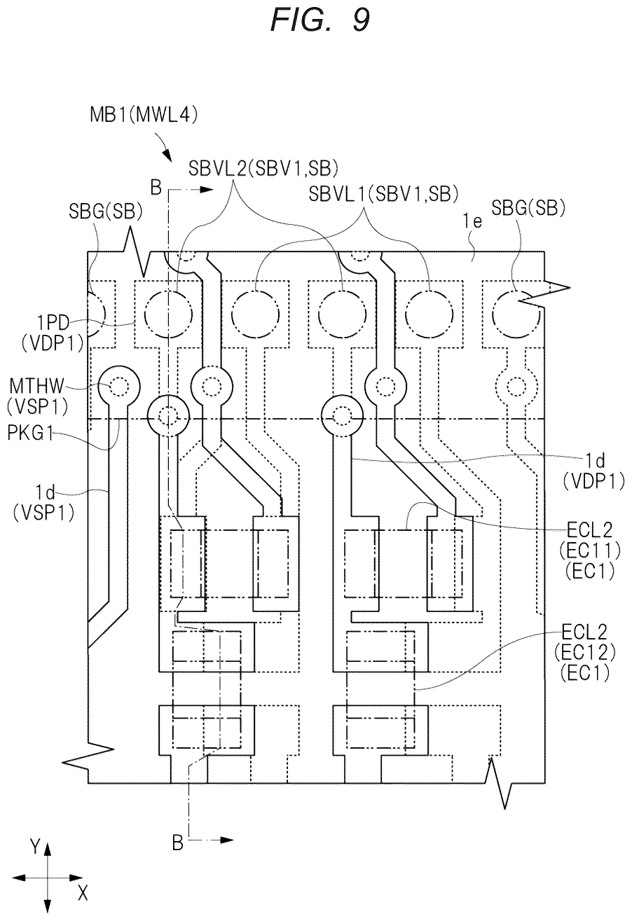

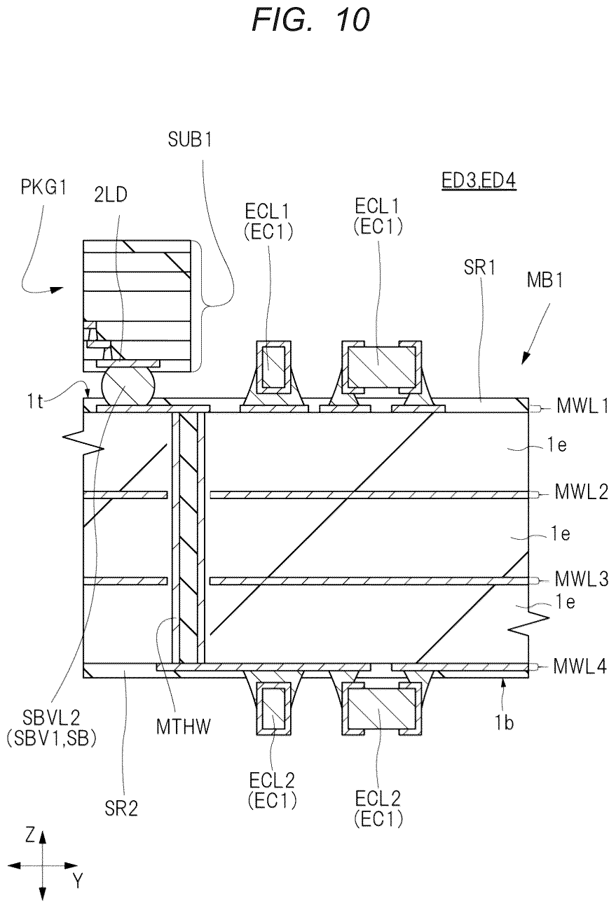

Next, a modified example of the layout of the electronic component EC1 described using FIG. 6 will be explained. FIG. 8 is an enlarged plan view showing an example of a layout in a wiring layer of the uppermost layer of the mounting board, which is a modified example of FIG. 6. FIG. 9 is an enlarged plan view showing an example of a layout in a wiring layer of the lowermost layer of the mounting board shown in FIG. 8. FIG. 10 is an enlarged cross-sectional view along the B-B line shown in FIGS. 8 and 9.

In FIG. 8, the shape of the wiring layer MWL1 is shown with a solid line in a state where the insulating film SR1 shown in FIG. 10 is removed. In FIG. 9, the shape of the wiring layer MWL4 is shown with a solid line in a state where the insulating film SR2 shown in FIG. 10 is removed, and the outline of the wiring layer MWL1 shown in FIG. 8 is shown with a dotted line. Also, in FIGS. 8 and 9, the outline of the semiconductor device PKG1 shown in FIG. 1, the outline of the terminal SBV1 shown in FIG. 4, and the outline of the electronic components EC1 are shown with a two-dot chain line.

Electronic device ED3, which is a modified example, differs from the electronic device ED1 described using FIGS. 1 to 6 in the following points. As shown in FIG. 10, the electronic components EC1 for the filter circuit provided in the electronic device ED3 include the electronic components ECL1 mounted on the upper surface 1t of the mounting board MB1 and the electronic components ECL2 mounted on the lower surface 1b of the mounting board MB1.

Each of the electronic components EC1 may have different mounting areas (in other words, the size of the electronic component EC1 in a plan view) depending on electrical characteristics such as capacitance, inductance, or resistance value. In this modified example, the mounting area of each of the electronic components EC1 shown in FIGS. 8 to 10 is larger than the mounting area of the electronic components EC1 shown in FIGS. 2 and 6.

When the mounting area of the electronic component EC1 is large, it may become difficult to place all of the numerous electronic components EC1 only on the upper surface 1t. Alternatively, even if all the electronic components EC1 could be placed on the upper surface 1t, there may be concerns about the performance of the filter circuit deteriorating due to the increased path distance from some of the electronic components EC1 to the solder ball SB. Alternatively, if the array spacing of the solder balls SB is widened in response to the increase in the mounting area of the electronic component EC1, the integration level of the semiconductor device PKG1 may decrease.

Therefore, in this modified example, as shown in FIG. 10, by mounting some of the electronic components EC1 on the lower surface 1b, the space shortage on the upper surface 1t is compensated. The electronic component ECL2 mounted on the lower surface 1b and the power-supply terminal SBVL2 are electrically connected via the through-hole wiring MTHW arranged in the immediate vicinity of the power-supply terminal SBVL2. The path connecting the power-supply terminal SBVL2 and the electronic component ECL2 is longer by the path distance of the through-hole wiring MTHW compared to the path connecting the power-supply terminal SBVL1 and the electronic component ECL1. However, in this modified example, the extension of the path distance can be minimized.

Also, in the example shown in FIGS. 8 and 9, the power-supply terminals SBV1 provided in the electronic device ED3 include the power-supply terminals SBVL1 connected to any two or more of the electronic components ECL1 and the power-supply terminals SBVL2 connected to any two or more of the electronic components ECL2. In the four or more of the plurality of power-supply terminals SBV1 arranged in the outermost row, the plurality of power-supply terminals SBVL1 and the plurality of power-supply terminals SBVL2 are alternately arranged one by one.

Specifically, in this modified example, the power-supply terminal SBVL1 connected to the electronic component ECL1 mounted on the upper surface 1t of the mounting board MB1 and the power-supply terminal SBVL2 connected to the electronic component ECL2 mounted on the lower surface 1b of the mounting board MB1 are alternately arranged one by one along the X direction (see FIG. 8).

In this modified example, when the power-supply terminals SBVL1 and the power-supply terminals SBVL2 are alternately arranged next to each other, the wiring length of the portion connecting the electronic component EC1 and the power-supply terminal SBV1 among the wirings 1d shown in FIGS. 8 and 9 can be shortened. In other words, according to this modified example, since the power-supply terminals SBVL1 and the power-supply terminals SBVL2 are alternately arranged next to each other, the path distance from the filter circuits to the power-supply terminals SBV1 can be shortened. As a result, the risk of noise re-entering the power-supply-potential supply path VDP1, where noise has been filtered by the filter circuit, can be reduced.

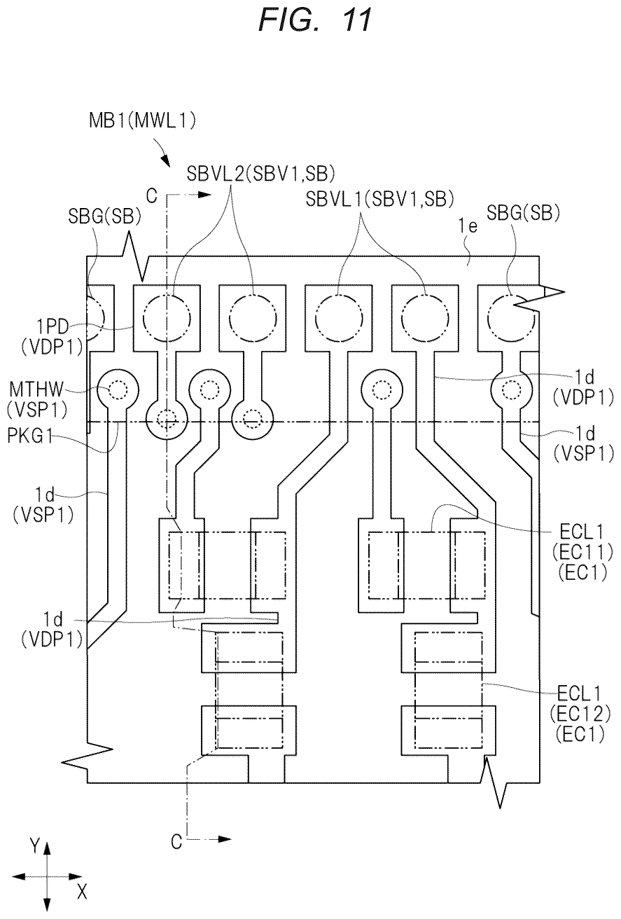

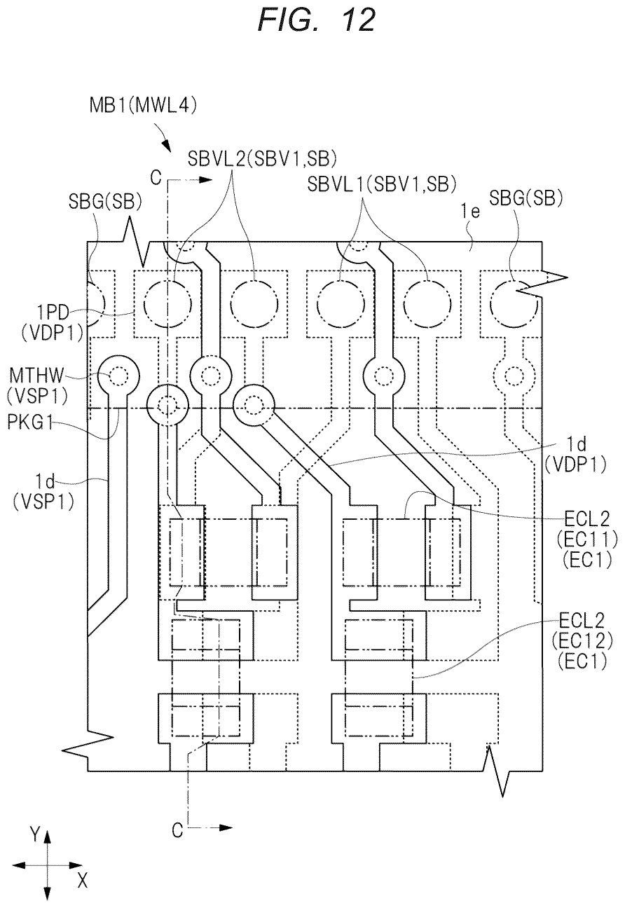

By the way, in the case of the electronic device ED3 shown in FIGS. 8 to 10 (see FIG. 10), the power-supply terminals SBVL1 and SBVL2 are alternately arranged one by one. However, as shown in FIGS. 11 and 12, as a modified example, the power-supply terminals SBVL1 and the power-supply terminals SBVL2 may be alternately arranged two by two.

FIG. 11 is an enlarged plan view showing an example of a layout in the wiring layer of the uppermost layer of the mounting board, which is a modified example of FIG. 8. FIG. 12 is an enlarged plan view showing an example of a layout in the wiring layer of the lowermost layer of the mounting board shown in FIG. 11. The enlarged cross-sectional view along the C-C line shown in FIGS. 11 and 12 is the same as FIG. 10, so it is omitted, and the code of the electronic device ED4 is attached to FIG. 10.

In FIG. 11, the shape of the wiring layer MWL1 is shown with a solid line in a state where the insulating film SR1 shown in FIG. 10 is removed. In FIG. 12, the shape of the wiring layer MWL4 is shown with a solid line in a state where the insulating film SR2 shown in FIG. 10 is removed, and the outline of the wiring layer MWL1 shown in FIG. 11 is shown with a dotted line. Also, in FIGS. 11 and 12, the outline of the semiconductor device PKG1 shown in FIG. 1, the outline of the terminal SBV1 shown in FIG. 4, and the outline of the electronic components EC1 are shown with a two-dot chain line.

The electronic device ED4 shown in FIGS. 10 to 12 (see FIG. 10) differs from the electronic device ED3 (see FIG. 10) in the following points. The power-supply terminals SBV1 provided in the electronic device ED4 include a pair of power-supply terminals SBVL1 connected to any two or more of the electronic components ECL1 and a pair of power-supply terminals SBVL2 connected to any two or more of the electronic components ECL2. In the four or more power-supply terminals SBV1 arranged in the outermost row, the pair of power-supply terminals SBVL1 and the pair of power-supply terminals SBVL2 are arranged next to each other.

Specifically, in this modified example, the power-supply terminal SBVL1 connected to the electronic component ECL1 mounted on the upper surface 1t of the mounting board MB1 and the power-supply terminal SBVL2 connected to the electronic component ECL2 mounted on the lower surface 1b of the mounting board MB1 are alternately arranged two by two along the X direction (see FIG. 8).

As can be seen from the comparison between FIG. 8 and FIG. 11, or the comparison between FIG. 9 and FIG. 12, the path distance of the wiring 1d connecting the power-supply terminal SBV1 and the filter circuit is shorter in the example shown in FIGS. 8 and 9. Therefore, it is particularly preferable that the power-supply terminals SBVL1 and the power-supply terminals SBVL2 are alternately arranged one by one.

However, even in the case where the power-supply terminals SBVL1 and the power-supply terminals SBVL2 are alternately arranged two by two, as in the modified example shown in FIGS. 11 and 12, the path distance of the wiring 1d connecting the power-supply terminal SBV1 and the filter circuit does not become extremely long. Therefore, as long as it is within the extent of the modified examples shown in FIG. 11 and FIG. 12, it is permissible even if the power-supply terminals SBVL1 are adjacent to each other, or if the power-supply terminals SBVL2 are adjacent to each other.

Each of the electronic devices ED3 and ED4 shown in FIG. 10 is similar to the electronic device ED1 described using FIGS. 1 to 6, except for the differences mentioned above. Therefore, overlapping descriptions are omitted.

### Semiconductor Device

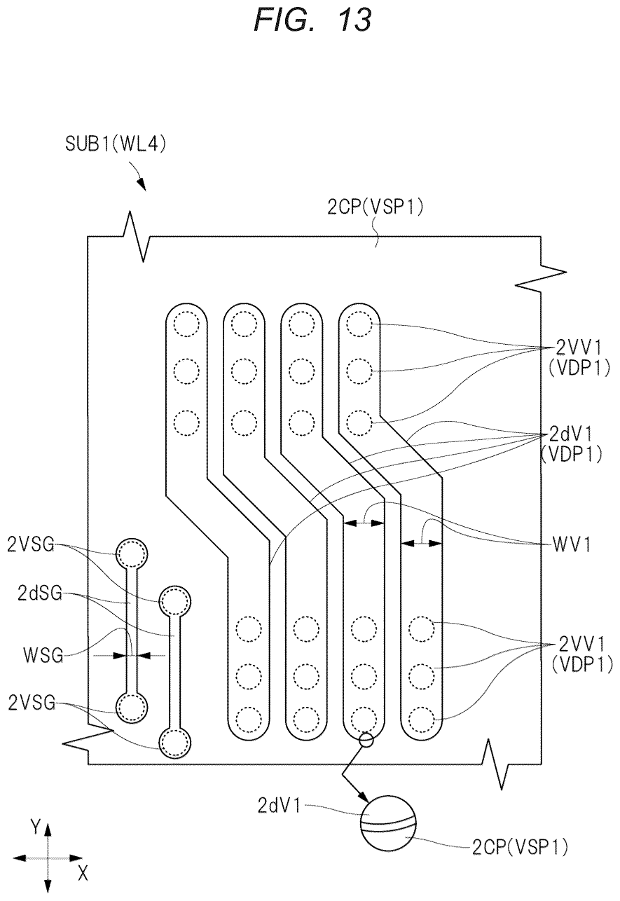

Next, from the perspective of stabilizing the power-supply potential supplied to the circuit NSC1 described using FIG. 5 and others, a preferred embodiment of the semiconductor device shown in FIG. 3 and FIG. 4 will be described. FIG. 13 is an enlarged plan view showing an example of a wiring pattern in one of a plurality of wiring layers provided in the wiring substrate shown in FIG. 3. In FIG. 13, as an example, a portion of the wiring layer WL4, which is the fourth layer from the upper surface 2t side among the wiring layers shown in FIG. 3, is illustrated in an enlarged manner.

In FIG. 13, as an example of the conductor pattern arranged in the wiring layer WL4, four power-supply wirings 2dV1, two signal wirings 2dSG, and a large-area conductor pattern 2CP are illustrated. The conductor pattern 2CP is a conductor plane (ground plane) constituting the reference-potential supply path VSP1 that supplies the reference potential VSS1 shown in FIG. 5. Note that the four power-supply wirings 2dV1, the two signal wirings 2dSG, and the conductor pattern 2CP are separated from each other.

As shown in FIG. 4, the plurality of solder balls SB (terminals) includes a plurality of signal terminals SBSG connected to a transmission path (signal transmission path) of a signal. As shown in FIG. 13, the wiring substrate SUB1 includes the power-supply wiring 2dV1 electrically connected to the power-supply terminals SBV1 (see FIG. 4) and the signal wirings 2dSG electrically connected to the signal terminals SBSG (see FIG. 4). Each wiring width WV1 of the power-supply wiring 2dV1 is larger than each wiring width WSG of the signal wirings 2dSG.

As described above, regarding the power-supply-potential supply path VDP1 that supplies the power-supply potential VDD1 to the circuits NSC1 shown in FIG. 5, it is preferable that the power-supply-potential supply paths VDP1 are separated from each other to prevent interference between the circuits NSC1. Therefore, it is difficult to adopt a structure where the power-supply-potential supply paths VDP1 are connected to a large-area conductor pattern like a power plane.

Therefore, as shown in FIG. 13, it is preferable that each wiring width WV1 of the power-supply wirings 2dV1 are large. When each wiring width WV1 of the power-supply wirings 2dV1 is large, it is possible to increase the cross-sectional area of the path of the power-supply-potential supply path VDP1. This allows the power-supply potential VDD1 supplied to the circuits NSC1 to be stabilized.

Furthermore, from the perspective of increasing the conductive path cross-sectional area between the wiring layers, the following structure is preferable. That is, it is preferable that the number of the via wirings connected to the power-supply wirings is greater than the number of the via wirings connected to the signal wirings.

As shown in FIG. 13, a plurality of signal-via wirings 2VSG is connected to each of the plurality of signal wirings 2dSG. In the example shown in FIG. 13, two signal-via wirings 2VSG are connected to one signal wiring 2dSG. Of the two signal-via wirings 2VSG, one is connected to the wiring layer WL3 shown in FIG. 3, and the other is connected to the wiring layer WL5.

As shown in FIG. 13, a plurality of power-supply-via wirings 2VV1 is connected to each of the plurality of power-supply wirings 2dV1. In the example shown in FIG. 13, six power supply via wirings 2VV1 are connected to one power-supply wiring 2dV1. Of the six power-supply-via wirings 2VV1, for example, three are connected to the wiring layer WL3 shown in FIG. 3, and the other three are connected to the wiring layer WL5.

As shown in FIG. 13, the number of power-supply-via wirings 2VV1 connected to each of the plurality of power-supply wirings 2dV1 is greater than the number of signal-via wirings 2VSG connected to each of the plurality of signal wirings 2dSG.

By increasing the number of power supplies via wiring 2VV1, it is possible to increase the cross-sectional area of the transmission path between adjacent wiring layers in the thickness direction of the semiconductor device PKG1 (see FIG. 3). As a result, the power-supply potential VDD1 supplied to the circuits NSC1 can be stabilized.

Although the invention made by the present inventor has been specifically described based on the embodiment, the present invention is not limited to the above embodiment, and it is needless to say that various modifications can be made without departing from the gist thereof.

What is claimed is:

1. An electronic device comprising:
a mounting board having a first surface and a second surface opposite the first surface;
a semiconductor device mounted on the first surface of the mounting board; and
a plurality of electronic components mounted on the mounting board,
wherein the semiconductor device includes:
a wiring substrate having a third surface facing the first surface of the mounting board and a fourth surface opposite the third surface; and
a semiconductor chip mounted on the fourth surface of the wiring substrate,
wherein the semiconductor device is electrically connected to the mounting board via a plurality of terminals arranged in a grid on the third surface of the wiring substrate,
wherein the semiconductor chip includes:
a core circuit including an arithmetic processing circuit; and
a plurality of first circuits different from the core circuit,
wherein the plurality of terminals includes a plurality of first power supply terminals that is capable of supplying a power supply potential to the plurality of first circuits, respectively,
wherein each of the plurality of electronic components has a passive element,
wherein the plurality of first power supply terminals and the plurality of electronic components are electrically connected with each other,
wherein the plurality of electronic components is mounted on the first surface of the mounting board, and
wherein at least four or more of the plurality of first power supply terminals are arranged in an outermost row of the plurality of terminals, which is arranged in the grid, such that the four or more of the plurality of first power supply terminals are arranged next to each other, and such that the four or more of the plurality of first power supply terminals are arranged continuously.

2. The electronic device according to claim 1, wherein each of the plurality of first power supply terminals is electrically connected to at least two or more of the plurality of electronic components.

3. The electronic device according to claim 2, wherein the two or more of the plurality of electronic components include a chip inductor having an inductor element and a chip capacitor having a capacitor element.

4. The electronic device according to claim 1,
wherein the plurality of terminals includes a plurality of second power supply terminals that is capable of supplying a power supply potential to the core circuit, and
wherein, in the plurality of terminals arranged in the grid, each of the plurality of second power supply terminals is arranged in an inner row than the plurality of first power supply terminals.

5. The electronic device according to claim 1, wherein all of the plurality of electronic components are mounted on the first surface of the mounting board.

6. The electronic device according to claim 1, wherein the plurality of electronic components includes a plurality of first electronic components mounted on the first surface of the mounting board and a plurality of second electronic components mounted on the second surface of the mounting board.

7. The electronic device according to claim 6,
wherein the plurality of first power supply terminals includes:
a plurality of third power supply terminals connected to any two or more of the plurality of first electronic components; and
a plurality of fourth power supply terminals connected to any two or more of the plurality of second electronic components, and
wherein, in the four or more of the plurality of first power supply terminals, the plurality of third power supply terminals and the plurality of fourth power supply terminals are alternately arranged one by one.

8. The electronic device according to claim 6,
wherein the plurality of first power supply terminals includes:
a pair of third power supply terminals connected to any two or more of the plurality of first electronic components; and
a pair of fourth power supply terminals connected to any two or more of the plurality of second electronic components, and
wherein, in the four or more of the plurality of first power supply terminals, the pair of third power supply terminals and the pair of fourth power supply terminals are arranged next to each other.

9. The electronic device according to claim 1, wherein the plurality of first circuits includes an input/output circuit that is capable of inputting and outputting a signal.

10. The electronic device according to claim 1, wherein the plurality of first circuits includes a PLL (Phase Locked Loop) circuit.

11. The electronic device according to claim 1,
wherein the plurality of terminals includes a plurality of signal terminals connected to a transmission path of a signal,
wherein the wiring substrate includes:
a plurality of first power supply wirings electrically connected to the plurality of first power supply terminals; and
a plurality of signal wirings electrically connected to the plurality of signal terminals, and
wherein a wiring width of each of the plurality of first power supply wirings is larger than a wiring width of each of the plurality of signal wirings.

12. The electronic device according to claim 11,
wherein a plurality of signal via wirings is connected to each of the plurality of signal wirings,
wherein a plurality of first power supply via wirings is connected to each of the plurality of first power supply wirings, and
wherein a number of the plurality of first power supply via wirings is greater than a number of the plurality of signal via wirings.

13. The electronic device according to claim 1, wherein the plurality of first power supply terminals includes:
a first terminal to which a first power supply potential is supplied; and
a second terminal to which a second power supply potential, which is different from the first power supply potential, is supplied.

14. A semiconductor device comprising:
a wiring substrate having an upper surface and a lower surface opposite the upper surface;
a semiconductor chip mounted on the upper surface of the wiring substrate; and
a plurality of terminals arranged in a grid on the lower surface,
wherein the semiconductor chip includes:
a core circuit including an arithmetic processing circuit; and
a plurality of first circuits different from the core circuit,
wherein the plurality of terminals includes a plurality of first power supply terminals that is capable of supplying a power supply potential to the plurality of first circuits, respectively, and
wherein at least four or more of the plurality of first power supply terminals are arranged in an outermost row of the plurality of terminals, which is arranged in the grid, such that the four or more of the plurality of first power supply terminals are arranged next to each other, and such that the four or more of the plurality of first power supply terminals are arranged continuously.

15. The semiconductor device according to claim 14,
wherein the plurality of terminals includes a plurality of second power supply terminals that is capable of supplying a power supply potential to the core circuit, and
wherein, in the plurality of terminals arranged in the grid, each of the plurality of second power supply terminals is arranged in an inner row than the plurality of first power supply terminals.

16. The semiconductor device according to claim 14, wherein the plurality of first circuits includes an input/output circuit that is capable of inputting and outputting a signal.

17. The semiconductor device according to claim 14, wherein the plurality of first circuits includes a PLL (Phase Locked Loop) circuit.

18. The semiconductor device according to claim 14,
wherein the plurality of terminals includes a plurality of signal terminals connected to a transmission path of a signal,
wherein the wiring substrate includes:
a plurality of first power supply wirings electrically connected to the plurality of first power supply terminals; and
a plurality of signal wirings electrically connected to the plurality of signal terminals, and
wherein a wiring width of each of the plurality of first power supply wirings is larger than a wiring width of each of the plurality of signal wirings.

19. The semiconductor device according to claim 18,
wherein a plurality of signal via wirings is connected to each of the plurality of signal wirings,
wherein a plurality of first power supply via wirings is connected to each of the plurality of first power supply wirings, and
wherein a number of the plurality of first power supply via wirings is greater than a number of the plurality of signal via wirings.
